(19) United States
(12) Patent Application Publication
(10) Pub. No.: US 2004/0223529 A1
(43) Pub. Date: Nov. 11, 2004

(54) Semiconductor laser cladding layers

(75) Inventors: John D. Bruno, Bowie, MD (US); Frederick Jay Towner, Fulton, MD (US)

Correspondence Address: Alan G. Towner, Pietragallo, Bosick & Gordon, One Oxford Centre, 38th Floor, 301 Grant Street, Pittsburgh, PA, 15219, US

(73) Assignee: Maxion Technologies, Inc., Hyattsville, MD

(21) Appl. No.: 10/841,859

(22) Filed: May 7, 2004

Related U.S. Application Data
(60) Provisional application No. 60/468,833, filed on May 8, 2003.

(51) Int. Cl. H01S 5/00

(52) U.S. Cl. 372/45; 372/46

(57) ABSTRACT

Cladding layers for semiconductor lasers provide improved heat transfer and optical confinement properties. The cladding layers may comprise superlattices such as AlSb/GaAs, AlSb/AlAs, AlSb/GaSb/AlAs, AlGaSb/AlGaAs and AlSb/AlGaAs. The cladding layers may also comprise Al-As-Sb ternary alloys or Al-Ga-As-Sb quaternary alloys. Such cladding layers may be used in interband cascade lasers or other types of semiconductor lasers to significantly increase heat flow out of the active light-emitting region of the device, while providing improved optical confinement characteristics.

### CROSS-REFERENCE TO RELATED APPLICATION

This application claims the benefit of U.S. Provisional Patent Application Ser. No. 60/468,833 filed May 8, 2003, which is incorporated herein by reference.

### FIELD OF THE INVENTION

The present invention relates to semiconductor laser cladding layers, and more particularly relates to cladding layer materials for use in devices such as interband cascade (IC) lasers to provide improved heat transfer and optical confinement characteristics.

### BACKGROUND INFORMATION

Semiconductor lasers have cladding layers which serve to provide optical confinement for the active region of the laser, and which may also serve as electrical current conductors for the device. For example, in edge-emitting interband cascade lasers, cladding layers are provided on either side of the active region. Such cladding layers may comprise doped AlSb/InAs superlattices having thicknesses of about 2 μm. These cladding layers transport charge between the electrical contacts and the active region. They also provide refractive indices lower than that of the active region, thereby confining the optical energy emitted by the device to the active region. Some examples of interband cascade lasers are described in U.S. Pat. Nos. 5,588,015 and 6,404,791, which are incorporated herein by reference.

Conventional semiconductor laser designs suffer from unwanted heat buildup in the active region. Although conventional cladding layers may have relatively low refractive indices which provide adequate optical confinement properties, they are not very good thermal conductors. A need exists for semiconductor laser cladding layers having significantly improved heat transfer characteristics and optical confinement properties.

### SUMMARY OF THE INVENTION

The present invention provides semiconductor laser cladding layers with improved combinations of heat transfer and optical confinement properties. The present cladding materials may replace an AlSb/InAs superlattice as a cladding layer in an IC laser to improve heat flow through the cladding layer via an increase in thermal conductivity. The present cladding layers also improve optical confinement of light within the active region since their refractive indices are significantly lower than that of conventional AlSb/InAs superlattices.

An aspect of the present invention is to provide a semiconductor laser cladding material comprising an AlSb/GaAs superlattice, an AlSb/GaSb/AlAs superlattice, an AlGaSb/AlGaAs superlattice, and/or an AlSb/AlGaAs superlattice.

Another aspect of the present invention is to provide an interband cascade laser comprising an interband cascade active region, a first cladding layer on one side of the active region, and a second cladding layer on another side of the active region, wherein at least one of the cladding layers comprises an AlSb/GaAs superlattice, an AlSb/GaSb/AlAs superlattice, an AlGaSb/AlGaAs superlattice, an AlSb/AlGaAs superlattice, an AlSb/AlAs superlattice, a quaternary alloy comprising Al, Ga, As and Sb, and/or a ternary alloy comprising Al, As and Sb.

A further aspect of the present invention is to provide a method of making a semiconductor laser superlattice cladding layer, the method comprising depositing layers of at least three different binary materials on a substrate.

Another aspect of the present invention is to provide a method of making a semiconductor laser superlattice cladding layer, the method comprising depositing layers of at least two different ternary materials on a substrate

These and other aspects of the present invention will be more apparent from the following description.

### BRIEF DESCRIPTION OF THE DRAWINGS

FIG. 1 is a partially schematic cross sectional view of a semiconductor laser including improved cladding layers in accordance with an embodiment of the present invention.

FIG. 2 is a partially schematic cross sectional view of an interband cascade laser structure including a bottom cladding layer in accordance with an embodiment of the present invention.

FIG. 3 is a partially schematic cross sectional view of another interband cascade laser structure including a bottom cladding layer in accordance with another embodiment of the present invention.

FIG. 4 is a partially schematic cross sectional view of a further interband cascade laser structure including a top cladding layer in accordance with a further embodiment of the present invention.

FIG. 5 is an x-ray diffraction spectrum for an AlSb/AlAs superlattice cladding layer in accordance with an embodiment of the present invention.

FIG. 6 is an x-ray diffraction spectrum for an AlAsSb ternary alloy cladding layer in accordance with another embodiment of the present invention.

### DETAILED DESCRIPTION

Improved cladding layer materials are provided for semiconductor lasers such as interband cascade (IC) lasers having better thermal and optical properties, thereby allowing higher temperature laser operation. The cladding materials have higher thermal conductivities and lower refractive indices than typical materials used for semiconductor laser cladding layers. For example, the present cladding layers may be used in place of an AlSb/InAs superlattice as a cladding layer to improve heat flow out of the active region of IC lasers. Also, the present cladding layers allow for better optical confinement of laser light within the active region and, therefore, increased overlap of the optical mode with the gain medium.

As used herein, the terms “active light-emitting region” and “active region” mean the region of a semiconductor laser in which light is generated for radiation from the device. The light is typically coherent and may comprise a single wavelength or multiple wavelengths within any desired range, e.g., visible, near infrared, mid infrared, etc. In one embodiment, the active light-emitting region is an interband cascade structure, for example, as described in U.S. Pat. Nos. 5,588,015 and 6,404,791.

As used herein, the term “cladding layer” means any type of cladding, reflector or mirror layer located outside of the active region of the semiconductor laser which provides the desired optical performance for the device, such as confining, reflecting or guiding the generated light in a desired direction. In some devices, the cladding layer may also carry electrical current to or from the active region.

The term “superlattice” means a structure comprised of a multiply repeated unit, with the unit consisting of a definite sequence of layers of different materials with specific thicknesses. For example, an AlSb/GaAs superlattice comprises multiply repeating units each consisting of AlSb and GaAs layers. In such a superlattice, each AlSb layer may have controlled amounts of Al and Sb, and each GaAs layer may have controlled amounts of Ga and As. As another example, an AlSb/GaSb/AlAs superlattice comprises multiply repeated units consisting of AlSb, GaSb and AlAs layers in any desired order.

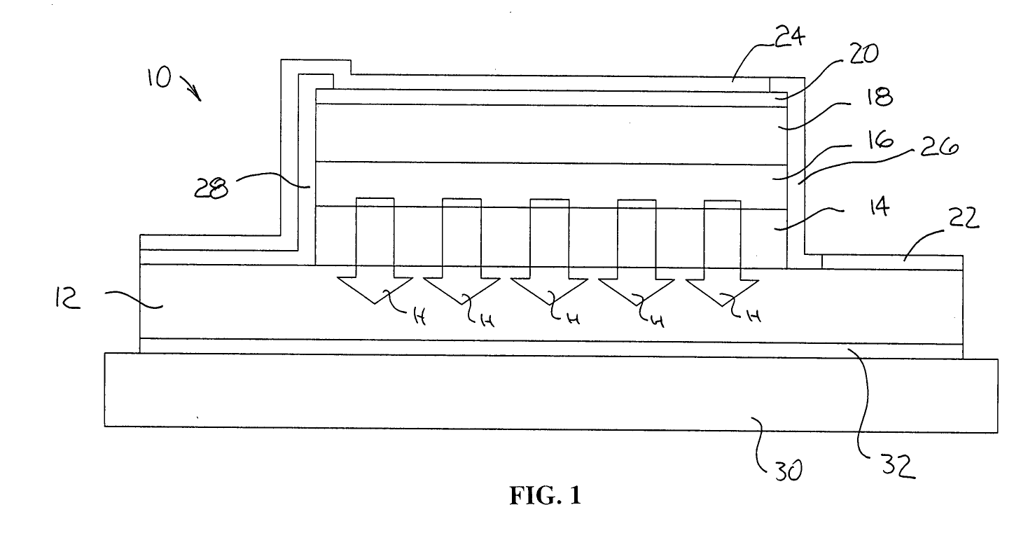

FIG. 1 illustrates a semiconductor laser 10 in accordance with an embodiment of the present invention. The laser 10 includes an electrically conductive substrate 12 made of doped GaSb or any other suitable material having a suitable thickness, e.g., about 100 μm. A bottom cladding layer 14 is deposited on the substrate 12. The laser 10 includes an active light-emitting region 16 deposited on the bottom cladding-layer 14. For example, the active region 16 may comprise an interband cascade structure. A typical thickness of the active region 16 is from about 1 to about 2 μm. A top cladding layer 18 is deposited on the active region 16. The cladding layers 14 and 18 act to optically confine light within the active region 16 of the device to thereby form a waveguide for the light. A top contact layer 20 comprising doped GaSb or the like is deposited on the top cladding layer 18.

As shown in FIG. 1, a bottom contact metal layer 22 such as Au, Ti and Au, or the like is deposited over a portion of the substrate 12. A top contact metal layer 24 contacts the top contact layer 20. An insulating material 26 such as SiO₂, Si₃N₄ or the like separates the top and bottom contact metal layers 24 and 22. Another insulating layer 28 made of SiO₂, Si₃N₄ or the like separates the top contact metal layer 24 from the substrate 12, bottom cladding layer 14, active region 16, and top cladding layer 18.

The laser 10 is mounted on a heat sink 30 made of copper, Au-coated copper, or the like. A solder metal layer 32 is used to attach the substrate 12 to the heat sink 30. As shown by the arrows H in FIG. 1, the use of a bottom cladding layer 14 of the present invention having high thermal conductivity results in improved heat transfer away from the active region 16 to the substrate 12 and heat sink 30.

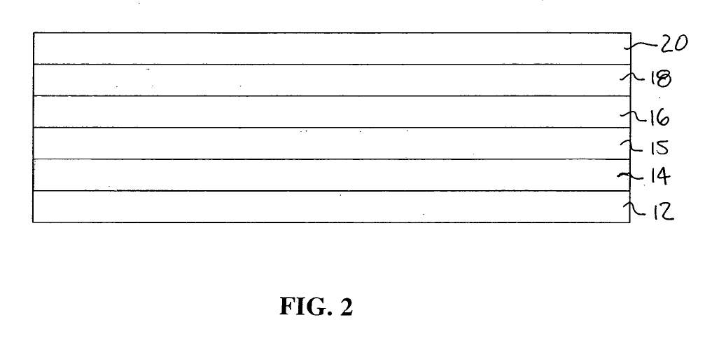

FIG. 2 illustrates a semiconductor laser structure including a bottom cladding layer in accordance with an embodiment of the present invention. The structure shown in FIG. 2 is similar to that shown in FIG. 1, with the exception of an additional bottom electrical contact layer 15 between the bottom cladding layer 14 and active region 16 made of a material such as p-doped GaSb having a thickness of about 0.3 microns. In the embodiment shown in FIG. 2, the substrate 12 may comprise a p-type GaSb substrate, an interband cascade active region 16, an n-doped AlSb/InAs superlattice top cladding layer 18, and an n-doped InAs contact layer 20. In accordance with the present invention, the bottom cladding layer 14 may comprise various materials, as set forth in more detail below.

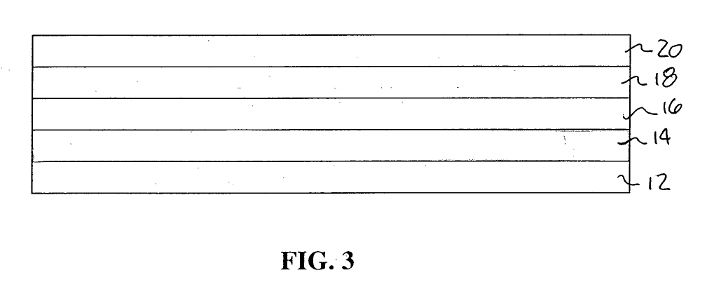

FIG. 3 illustrates a semiconductor laser structure similar to that shown in FIG. 1, which may comprise a p-type GaSb substrate 12, an interband cascade active region 16, an n-doped AlSb/InAs superlattice top cladding layer 18, and an n-doped InAs contact layer 20. In accordance with the present invention, the bottom cladding layer 14 comprises materials as set forth in detail below.

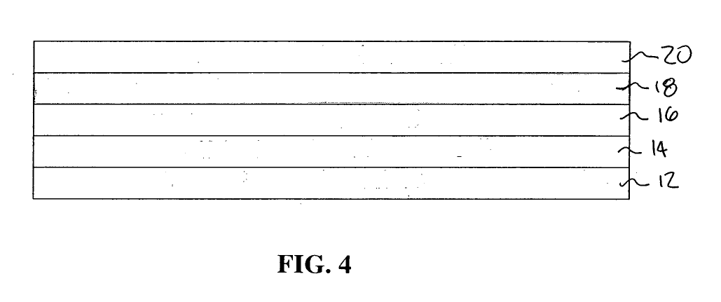

FIG. 4 illustrates a semiconductor laser structure similar to that shown in FIG. 1, comprising a p-type GaSb substrate, an n-doped AlSb/InAs bottom cladding layer 14, an interband cascade active region 16, and a p-doped GaSb contact layer 20. In the embodiment shown in FIG. 4, the top cladding layer 18 may comprise a material of the present invention, as more fully described below.

In accordance with the present invention, the semiconductor laser cladding materials, such as the bottom cladding layer 14 and/or the top cladding layer 18 shown in FIGS. 1-4, have a thermal conductivity of at least 5 W/m-K, preferably at least 6 W/m-K. The cladding materials also preferably have a low refractive index, e.g., less than or equal to 3.30, preferably less than or equal to 3.25.

One significant advantage of the superlattice cladding layer structures described herein is that the relative As-to-Sb composition of the overall structure is better controlled when the As and Sb are deposited in separate layers, rather than codeposited in a mixed As-Sb alloy. During superlattice depostion, the overall As-to-Sb composition is controlled by adjusting the relative thicknesses of the As-containing and Sb-containing layers. Separating the deposition of As and Sb into different layers avoids competition between these elements for allowed crystal lattice sites, and eliminates the requirement for precise control of the relative As and Sb deposition rates.

The laser cladding layers preferably have an in-plane lattice constant which substantially matches an in-plane lattice constant of a substrate upon which the superlattice is deposited, e.g., the lattice constants vary by less than 0.5 percent, preferably less than 0.3 percent. For example, when the substrate comprises GaSb or InAs, the in-plane lattice constant of the cladding layer preferably matches the in-plane lattice constant of the GaSb or InAs substrate.

The present laser cladding layers preferably have a total thickness of from about 0.5 to about 10 microns, for example, from about 1 to about 5 microns. As a particular example, the cladding layer has a thickness of from about 1.5 to about 3 microns.

Various cladding layer materials of the present invention are described in detail below.

### AlSb/GaAs Superlattice Cladding Layers

The cladding layer(s) may comprise an AlSb/GaAs superlattice having layers of AlSb and GaAs. The AlSb and GaAs layers preferably have a thickness ratio AlSb:GaAs of from about 3:1 to about 13:1. For example, when the AlSb/GaAs superlattice is deposited on a GaSb substrate, the AlSb:GaAs thickness ratio is preferably from about 10:1 to about 12:1. When the AlSb/GaAs superlattice is deposited on an InAs substrate, the AlSb:GaAs thickness ratio is preferably from about 4:1 to about 6:1.

Each AlSb layer preferably has an average thickness of from about 5 to about 100 Å, more preferably from about 10 to about 50 Å. Each GaAs layer preferably has an average thickness of from about 1 to about 10 Å, more preferably from about 2 to about 5 Å.

### AlSb/GaSb/AlAs Superlattice Cladding Layers

The cladding layer(s) may comprise an AlSb/GaSb/AlAs superlattice having layers of AlSb, GaSb and AlAs. The layers of the AlSb/GaSb/AlAs superlattice may be deposited in any desired order. For example, the AlSb layers may be deposited on the AlAs layers, the GaSb layers may be deposited on the AlSb layers, and the AlAs layers may be deposited on the GaSb layers. In another embodiment, the AlSb layers may be deposited on the GaSb layers, the AlAs layers may be deposited on the AlSb layers, and the GaSb layers may be deposited on the AlAs layers. In a further embodiment, the GaSb layers may be deposited between each of the AlAs and AlSb layers. In another embodiment, the AlAs layers may be deposited between each of the GaSb and AlSb layers. In a further embodiment, the AlSb layers may be deposited between each of the GaSb and AlAs layers.

The AlSb and AlAs layers may have an AlSb:AlAs thickness ratio of from about 3:1 to about 13:1. For example, when the cladding layer is deposited on a GaSb substrate, the AlSb:AlAs thickness ratio may be from about 10:1 to about 12:1. When the cladding is deposited on an InAs substrate, the AlSb:AlAs thickness ratio may be from about 4:1 to about 6:1.

Each of the AlSb layers may have an average thickness of from about 5 to about 100 Å, preferably from about 10 to about 50 Å. Each of the GaSb layers may have an average thickness of from about 1 to about 100 Å, preferably from about 2 to about 20 Å. Each of the AlAs layers may have an average thickness of from about 1 to about 10 Å, preferably from about 2 to about 5 Å.

### AlGaSb/AlGaAs Superlattice Cladding Layers

The cladding layer(s) may comprise an AlGaSb/AlGaAs superlattice having layers of AlGaSb and AlGaAs. The AlGaSb and AlGaAs layers may have an AlGaSb:AlGaAs thickness ratio of from about 3:1 to about 14:1. For example, when the cladding layer is deposited on a GaSb substrate, the AlGaSb:AlGaAs thickness ratio may be from about 11:1 to about 13:1. When the cladding layer is deposited on an InAs substrate, the AlGaSb:AlGaAs thickness ratio may be from about 4:1 to about 6:1.

Each AlGaSb layer may have an average thickness of from about 5 to about 100 Å, preferably from about 10 to about 50 Å. Each AlGaAs layer may have an average thickness of from about 1 to about 10 Å, preferably from about 2 to about 5 Å.

The AlGaSb may be of the formula Al₁₋ₓGaₓSb, where x is from about 0.01 to about 0.5. Preferably, x is from about 0.05 to about 0.10.

The AlGaAs may be of the formula A_{1-y}Ga_{y}As, where y is from about 0.01 to about 0.5. Preferably, y may be from about 0.05 to about 0.10.

In the foregoing formulas, the values of x and y may be substantially equal. For example, x and y may each range from about 0.01 to about 0.5. As a particular example, the values of x and y may each range from about 0.05 to about 0.10.

### AlSb/AlGaAs Superlattice Cladding Layers

The cladding layer(s) may comprise an AlSb/AlGaAs superlattice having layers of AlSb and AlGaAs. The AlSb and AlGaAs layers may have an AlSb:AlGaAs thickness ratio of from about 3:1 to about 13:1. For example, when the cladding layer is deposited on a GaSb substrate, the AlSb:AlGaAs thickness ratio may be from about 10:1 to about 12:1. When the cladding layer is deposited on an InAs substrate, the AlSb:AlGaAs thickness ratio may be from about 4:1 to about 6:1.

Each AlSb layer may have an average thickness of from about 5 to about 100 Å, preferably from about 10 to about 50 Å. Each AlGaAs layer may have an average thickness of from about 1 to about 10 Å, preferably from about 2 to about 5 Å.

The AlGaAs may be of the formula Al_{1-y}Ga_{y}As, where y is from about 0.01 to about 0.6. Preferably, y may range from about 0.05 to about 0.5. AlSb/AlAs Superlattice Cladding Layers

The cladding layer(s) may comprise an AlSb/AlAs superlattice having layers of AlSb and AlAs. The AlSb and AlAs layers may have an AlSb:AlAs thickness ratio of from about 3:1 to about 13:1. For example, when the cladding layer is deposited on a GaSb substrate, the AlSb:AlAs thickness ratio may be from about 10:1 to about 12:1. When the cladding layer is deposited on an InAs substrate, the AlSb:AlAs thickness ratio may be from about 4:1 to about 6:1.

Each AlSb layer may have an average thickness of from about 5 to about 100 Å, preferably from about 10 to about 50 Å. Each AlAs layer may have an average thickness of from about 1 to about 10 Å, preferably from about 2 to about 5 Å.

As a particular example, an AlSb/AlAs SL that is lattice matched to GaSb may comprise alternating layers of AlAs having thicknesses of 2.723 Å and AlSb having thicknesses of 30 Å. These layers are repeated as many times as need to obtain the desired total thickness. For example, to achieve a cladding thickness of about 2 μm, the AlSb/AlAs sequence can be repeated 611 times to obtain a total thickness of 1.999 μm.

Table 1 lists the refractive index of an AlSb/AlAs superlattice cladding material of the present invention versus an AlSb/InAs SL and a typical active region material comprising layers of GaSb, AlSb, InAs, GaInSb and AlInSb. Each AlSb layer of the AlSb/AlAs SL has an average thickness of from about 27 to about 33 Å, and each AlAs layer has an average thickness of from about 2.5 to about 3.0 Å.

TABLE 1

| | | Difference between |
|---|---|---|
| Structure | Refractive Index | cladding and active |
| AlSb/AlAs SL cladding | 3.16 | 0.33 |
| AlSb/InAs SL cladding | 3.37 | 0.12 |
| Typical active region | 3.49 | — |

In one embodiment, the relative thicknesses of the AlSb and AlAs may be chosen such that the average As composition of the SL is 8.3% (atomic). This composition is calculated using the equation: Average As composition (%)=(AlAs layer thickness)/[(AlAs layer thickness)+(AlSb layer thickness)]. This SL comprises levels of Al, As and Sb comparable to the ternary alloy AlAs_{0.083}Sb_{0.917}. Other combinations of AlAs and AlSb layer thicknesses, meeting the average SL As composition requirement stated above, may be used but should meet the further requirement that the critical thickness is not exceeded for either constituent layer relative to the GaSb lattice constant. It is noted that the cladding layer should have an in-plane lattice parameter substantially equal to that of to the GaSb substrate. The requirement of AlSb and AlAs layer thicknesses may be determined by ensuring that the average SL As composition, e.g., as calculated using the equation above, falls within the range 8.3%±0.5%. To further ensure adequate material quality, it is preferred that the AlAs and AlSb layer thicknesses meet the requirement that the average SL As composition falls within the range 8.3%±0.25%.

Several options exist for defining the carrier type and conductivity of the of the AlSb/AlAs SL: the SL can be left unintentionally doped; the SL can be P-doped using Be or Zn in one, or both, of the AlAs or AlSb layers; or the SL can be N-doped using either Te or Se in one, or both, of the AlAs or AlSb layers, or Si in AlAs layer (leaving the AlSb unintentionally doped).

### Al, Ga, As and Sb Quaternary Alloy Cladding Layers

The cladding layer(s) may comprise a quaternary alloy of Al, Ga, As and Sb. Such a quaternary alloy may be of the formula Al₁₋ₓGaₓAs_{y}Sb_{1-y}, where x is from about 0.01 to about 0.5, and y is from about 0.01 to about 0.2. For example, when the cladding layer is deposited on a GaSb substrate, the value of x may range from about 0.05 to about 0.2, and the value of y may range from about 0.05 to about 0.10. When the cladding layer is deposited on an InAs substrate, the value of x may range from about 0.05 to about 0.2, and the value of y may range from about 0.13 to about 0.19.

### Al, As and Sb Ternary Alloy Cladding Layers

The cladding layer(s) may comprise a ternary alloy of Al, As and Sb. Such a ternary alloy may be of the formula AlAsₓSb₁₋ₓ, where x is from about 0.01 to about 0.2. For example, the value of x may be from about 0.05 to about 0.15, preferably from about 0.07 to about 0.10, when the substrate upon which the cladding layer is deposited comprise GaSb. When the cladding layer is deposited on an InAs substrate, the value of x in the foregoing formula preferably ranges from about 0.13 to about 0.19.

Table 2 lists the refractive index of an AlAsSb ternary alloy cladding material of the present invention versus an AlSb/InAs SL and a typical active region material comprising layers of GaSb, AlSb, InAs, GaInSb and AlInSb.

TABLE 2

| | | Difference between |
|---|---|---|
| Structure | Refractive index | cladding and active |
| AlAs_{0.083}Sb_{0.917} cladding | 3.16 | 0.33 |
| AlSb/InAs SL cladding | 3.37 | 0.12 |
| Typical active region | 3.49 | — |

Several options exist for defining the carrier type and conductivity of the AlAsSb material: the AlAsSb can be left unintentionally doped; the AlAsSb can be P-doped using Be or Zn as the dopant; or the AlAsSb can be N-doped using Te or Se as the dopant.

The following examples are intended to illustrate various aspects of the invention, and are not intended to limit the scope of the invention.

### EXAMPLE 1

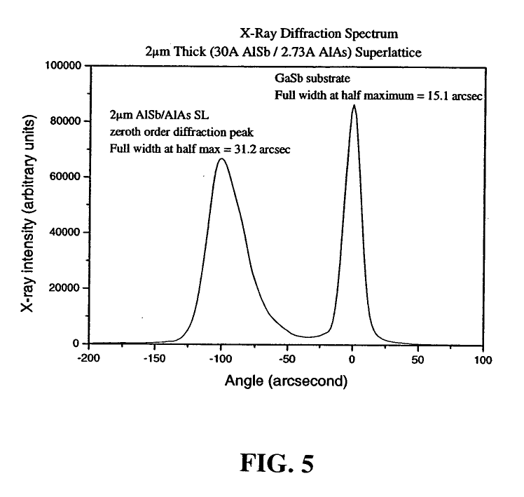

A prototype wafer comprising a 2 μm thick AlSb/AlAs SL structure was grown by molecular beam epitaxy (MBE). FIG. 5 is an x-ray diffraction spectrum taken on this sample. The good crystal quality of the AlSb/AlAs SL material is shown by the well-defined zeroth-order peak in the x-ray spectrum having a peak width about twice that of the GaSb substrate.

### EXAMPLE 2

An operational test of the AlSb/AlAs SL cladding was conducted. An interband cascade laser was fabricated in which the top cladding layer was composed of a 503 period (30 Å AlSb)/(2.73 Å AlAs) SL doped with Be. The intent of this design is to mount laser diodes top-side down on a copper heat sink. Hence the use of the low thermal resistance cladding material for the top cladding layer. X-ray diffraction measurements on this wafer show good crystal quality for the AlSb/AlAs SL cladding layer, as well as the rest of the epitaxial structure.

### EXAMPLE 3

Another operational test of the AlSb/AlAs SL cladding was conducted. An interband cascade laser was fabricated in which the bottom cladding layer was composed of an undoped 613 period (30 Å AlSb)/(2.73 Å AlAs) SL. X-ray diffraction measurements made on this sample also show good crystal quality for the AlSb/AlAs SL cladding as well as the rest of the laser structure growth on top. Measurements made on top-side up mounted lasers show about a 40% reduction in thermal resistance between the active region and heat sink, as compared to devices using AlSb/InAs SL top and bottom cladding layers.

### EXAMPLE 4

A further operational test was conducted in a similar manner as Example 3, except for changes in the P-doped GaSb bottom contact layer that have negligible effect on the thermal properties of the laser device. The crystal quality and thermal resistance characteristics are similar to those of the sample of Example 3.

### EXAMPLE 5

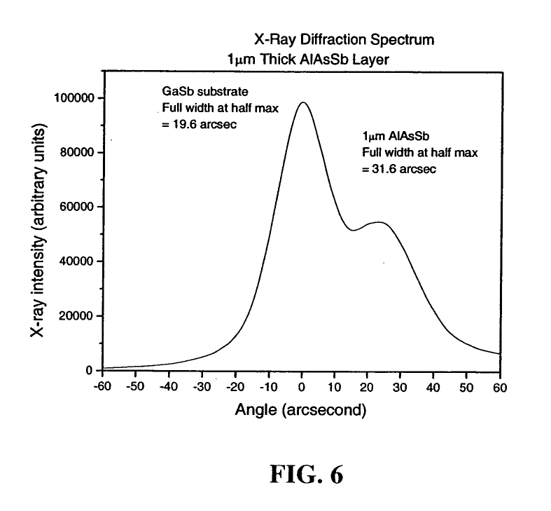

An AlAsSb cladding layer prototype was fabricated. The structure comprised a 1 μm thick AlAsSb layer grown by molecular beam epitaxy (MBE). FIG. 6 is an x-ray diffraction spectrum taken on this sample. The AlAsSb layer is slightly off of lattice match since its x-ray peak is about 25 arcsec on the high-angle side of the GaSb substrate peak. This corresponds to about 8.46% As in the AlAsSb layer, which is 0.14% over the 8.32% target. With this amount of lattice mismatch the AlAsSb crystal quality is still quite good as demonstrated by the AlAsSb x-ray peak width, which is less than twice that of the GaSb substrate.

### EXAMPLE 6

An operational test of the AlAsSb cladding layer was conducted. An interband cascade laser having a structure similar to that shown in FIG. 2 was fabricated in which the bottom cladding layer was undoped AlAsSb. A p-doped GaSb layer was inserted between the bottom cladding and active region to allow a path for current injection into the active region. The intent of this design is to mount the laser diode epi-side up on a copper heat sink, and enhance heat extraction through the bottom of the structure by using the AlAsSb cladding material. X-ray diffraction measurements on this wafer showed well-defined peaks from the various layers in the sample, but the crystal quality was significantly worse than typical as determined from the peak widths. Devices fabricated from this material worked as lasers, but had poor performance characteristics. These poor results were attributed to dislocations nucleated within the AlAsSb layer caused by lattice mismatch.

### EXAMPLE 7

Another operational test of the AlAsSb cladding material was conducted. An interband cascade laser having a structure similar to that shown in FIG. 3 was fabricated in which the bottom cladding layer was p-doped AlAsSb. This was another design that would improve heat extraction through the bottom cladding layer. In this design, the p-AlAsSb layer conducts current for carrier injection into the active region. As with the sample of Example 6, x-ray and laser test measurements indicated that the material quality was inferior. Again the poor results were attributed to dislocations nucleated within the AlAsSb layer caused by lattice mismatch.

### EXAMPLE 8

A further operational test of the AlAsSb cladding material was conducted. An interband cascade laser having a structure similar to that shown in FIG. 4 was fabricated in which the top cladding layer was p-doped AlAsSb. This laser is designed to improve heat extraction through the top cladding layer in an epi-side down configuration. The AlAsSb layer is p-doped to conduct current for carrier injection into the active region. X-ray measurements showed good crystal quality for this sample. The laser test results indicated better device quality than the samples of Examples 6 and 7, but still less than optimal. One or more issues associated with the design, growth or processing of this sample may have caused the poor performance.

### EXAMPLE 9

Another operational test of the AlAsSb cladding material was conducted. This sample was similar to that of Example 6, having an undoped AlAsSb lower cladding layer to enhance heat flow out the bottom of the structure. X-ray measurements indicated that a low level of dislocations were present. The device performance was much better than that of Example 6, but still not optimal.

### EXAMPLE 10

A further operational test of the AlAsSb cladding material was conducted. This design was the same as that of Example 9, except for a change in the p-GaSb bottom contact layer. X-ray and laser performance tests indicate good material and device quality.

Whereas particular embodiments of this invention have been described above for purposes of illustration, it will be evident to those skilled in the art that numerous variations of the details of the present invention may be made without departing from the invention as defined in the appended claims.

1. A semiconductor laser cladding material comprising:
an AlSb/GaAs superlattice;
an AlSb/GaSb/AlAs superlattice;
an AlGaSb/AlGaAs superlattice; and/or
an AlSb/AlGaAs superlattice.

2. The semiconductor laser cladding material of claim 1, wherein the material has a thermal conductivity of at least 5 W/m-K.

3. The semiconductor laser cladding material of claim 1, wherein the material has a refractive index less than or equal to 3.30.

4. The semiconductor laser cladding material of claim 1, wherein the material has an in-plane lattice constant which substantially matches an in-plane lattice constant of a substrate upon which the superlattice is deposited.

5. The semiconductor laser cladding material of claim 4, wherein the substrate comprises GaSb or InAs.

6. The semiconductor laser cladding material of claim 1, wherein the material has a total thickness of from about 0.5 to about 10 microns.

7. The semiconductor laser cladding material of claim 1, wherein the material has a total thickness of from about 1 to about 5 microns.

8. The semiconductor laser cladding material of claim 1, wherein the material has a total thickness of from about 1.5 to about 3 microns.

9. The semiconductor laser cladding material of claim 1, wherein the material is provided in an interband cascade laser.

10. The semiconductor laser cladding material of claim 1, wherein the material comprises an AlSb/GaAs superlattice having layers of AlSb and GaAs.

11. The semiconductor laser cladding material of claim 10, wherein the AlSb and GaAs layers have a thickness ratio AlSb:GaAs of from about 3:1 to about 13:1.

12. The semiconductor laser cladding material of claim 10, wherein the AlSb and GaAs layers have a thickness ratio AlSb:GaAs of from about 10:1 to about 12:1.

13. The semiconductor laser cladding material of claim 10, wherein the AlSb and GaAs layers have a thickness ratio AlSb:GaAs of from about 4:1 to about 6:1.

14. The semiconductor laser cladding material of claim 10, wherein each AlSb layer has an average thickness of from about 5 to about 100 Å, and each GaAs layer has an average thickness of from about 1 to about 10 Å.

15. The semiconductor laser cladding material of claim 10, wherein each AlSb layer has an average thickness of from about 10 to about 50 Å, and each GaAs layer has an average thickness of from about 2 to about 5 Å.

16. The semiconductor laser cladding material of claim 10, wherein the superlattice further comprises layers of AlAs.

17. The semiconductor laser cladding material of claim 1, wherein the material comprises an AlSb/GaSb/AlAs superlattice having layers of AlSb, GaSb and AlAs.

18. The semiconductor laser cladding material of claim 17, wherein the AlSb layers are deposited on the AlAs layers, the GaSb layers are deposited on the AlSb layers, and the AlAs layers are deposited on the GaSb layers.

19. The semiconductor laser cladding material of claim 17, wherein the AlSb layers are deposited on the GaSb layers, the AlAs layers are deposited on the AlSb layers, and the GaSb layers are deposited on the AlAs layers.

20. The semiconductor laser cladding material of claim 17, wherein the GaSb layers are deposited between each of the AlAs and AlSb layers.

21. The semiconductor laser cladding material of claim 17, wherein the AlAs layers are deposited between each of the GaSb and AlSb layers.

22. The semiconductor laser cladding material of claim 17, wherein the AlSb layers are deposited between each of the GaSb and AlAs layers.

23. The semiconductor laser cladding material of claim 17, wherein the AlSb and AlAs layers have an AlSb:AlAs thickness ratio of from about 3:1 to about 13:1.

24. The semiconductor laser cladding material of claim 17, wherein the AlSb and AlAs layers have an AlSb:AlAs thickness ratio of from about 10:1 to about 12:1.

25. The semiconductor laser cladding material of claim 17, wherein the AlSb and AlAs layers have an AlSb:AlAs thickness ratio of from about 4:1 to about 6:1.

26. The semiconductor laser cladding material of claim 17, wherein each of the AlSb layers has an average thickness of from about 5 to about 100 Å, each of the GaSb layers has an average thickness of from about 1 to about 100 Å, and each of the AlAs layers has an average thickness of from about 1 to about 10 Å.

27. The semiconductor laser cladding material of claim 17, wherein each of the AlSb layers has an average thickness of from about 10 to about 50 Å, each of the GaSb layers has an average thickness of from about 2 to about 20 Å, and each of the AlAs layers has an average thickness of from about 2 to about 5 Å.

28. The semiconductor laser cladding material of claim 1, wherein the material comprises an AlGaSb/AlGaAs superlattice having layers of AlGaSb and AlGaAs.

29. The semiconductor laser cladding material of claim 28, wherein the AlGaSb and AlGaAs layers have an AlGaSb:AlGaAs thickness ratio of from about 3:1 to about 14:1.

30. The semiconductor laser cladding material of claim 28, wherein the AlGaSb and AlGaAs layers have an AlGaSb:AlGaAs thickness ratio of from about 11:1 to about 13:1.

31. The semiconductor laser cladding material of claim 28, wherein the AlGaSb and AlGaAs layers have an AlGaSb:AlGaAs thickness ratio of from about 4:1 to about 6:1.

32. The semiconductor laser cladding material of claim 28, wherein each AlGaSb layer has an average thickness of from about 5 to about 100 Å, and each AlGaAs layer has an average thickness of from about 1 to about 10 Å.

33. The semiconductor laser cladding material of claim 28, wherein each AlGaSb layer has an average thickness of from about 10 to about 50 Å, and each AlGaAs layer has an average thickness of from about 2 to about 5 Å.

34. The semiconductor laser cladding material of claim 28, wherein the AlGaSb is of the formula Al₁₋ₓGaₓSb, where x is from about 0.01 to about 0.5.

35. The semiconductor laser cladding material of claim 34, wherein x is from about 0.05 to about 0.10.

36. The semiconductor laser cladding material of claim 28, wherein the AlGaAs is of the formula Al_{1-y}Ga_{y}As, where y is from about 0.01 to about 0.5.

37. The semiconductor laser cladding material of claim 36, wherein y is from about 0.05 to about 0.10.

38. The semiconductor laser cladding material of claim 28, wherein the AlGaSb is of the formula Al₁₋ₓGaₓSb, the AlGaAs is of the formula Al_{1-y}Ga_{y}As, and x and y are substantially equal.

39. The semiconductor laser cladding material of claim 38, wherein x and y are from about 0.01 to about 0.5.

40. The semiconductor laser cladding material of claim 38, wherein x and y are from about 0.05 to about 0.10.

41. The semiconductor laser cladding material of claim 1, wherein the material comprises an AlSb/AlGaAs superlattice having layers of AlSb and AlGaAs.

42. The semiconductor laser cladding material of claim 41, wherein the AlSb and AlGaAs layers have an AlSb:AlGaAs thickness ratio of from about 3:1 to about 13:1.

43. The semiconductor laser cladding material of claim 41, wherein the AlSb and AlGaAs layers have an AlSb:AlGaAs thickness ratio of from about 10:1 to about 12:1.

44. The semiconductor laser cladding material of claim 41, wherein the AlSb and AlGaAs layers have an AlSb:AlGaAs thickness ratio of from about 4:1 to about 6:1.

45. The semiconductor laser cladding material of claim 41, wherein each AlSb layer has an average thickness of from about 5 to about 100 Å, and each AlGaAs layer has an average thickness of from about 1 to about 10 Å.

46. The semiconductor laser cladding material of claim 41, wherein each AlSb layer has an average thickness of from about 10 to about 50 Å, and each AlGaAs layer has an average thickness of from about 2 to about 5 Å.

47. The semiconductor laser cladding material of claim 41, wherein the AlGaAs is of the formula Al_{1-y}Ga_{y}As, where y is from about 0.01 to about 0.6.

48. The semiconductor laser cladding material of claim 47, wherein y is from about 0.05 to about 0.5.

49. An interband cascade laser comprising:
an interband cascade active region;
a first cladding layer on one side of the active region; and
a second cladding layer on another side of the active region, wherein at least one of the first and second cladding layers comprises:
an AlSb/GaAs superlattice;
an AlSb/GaSb/AlAs superlattice;
an AlGaSb/AlGaAs superlattice;
an AlSb/AlGaAs superlattice;
an AlSb/AlAs superlattice;
a quaternary alloy comprising Al, Ga, As and Sb; and/or
a ternary alloy comprising Al, As and Sb.

50. The interband cascade laser of claim 49, wherein the at least one of the first and second cladding layers has a thermal conductivity of at least 5 W/m-K.

51. The interband cascade laser of claim 49, wherein the at least one of the first and second cladding layers has a refractive index less than or equal to 3.30.

52. The interband cascade laser of claim 49, wherein the superlattice has an in-plane lattice constant which substantially matches an in-plane lattice constant of a substrate upon which the superlattice is grown.

53. The interband cascade laser of claim 50, wherein the substrate comprises GaSb or InAs.

54. The interband cascade laser of claim 49, wherein the at least one of the first and second cladding layers has a total thickness of from about 0.5 to about 10 microns.

55. The interband cascade laser of claim 49, wherein the at least one of the first and second cladding layers has a total thickness of from about 1 to about 5 microns.

56. The interband cascade laser of claim 49, wherein the at least one of the first and second cladding layers has a total thickness of from about 1.5 to about 3 microns.

57. The interband cascade laser of claim 49, wherein the at least one of the first and second cladding layers comprises an AlSb/GaAs superlattice having layers of AlSb and GaAs.

58. The interband cascade laser of claim 49, wherein the at least one of the first and second cladding layers comprises an Al Sb/GaSb/AlAs superlattice having layers of AlSb, GaSb and AlAs.

59. The interband cascade laser of claim 49, wherein the at least one of the first and second cladding layers comprises an AlGaSb/AlGaAs superlattice having layers of AlGaSb and AlGaAs.

60. The interband cascade laser of claim 49, wherein the at least one of the first and second cladding layers comprises an AlSb/AlAs superlattice having layers of AlSb and AlAs.

61. The interband cascade laser of claim 60, wherein the AlSb and AlAs layers have an AlSb:AlAs thickness ratio of from about 3:1 to about 13:1.

62. The interband cascade laser of claim 60, wherein the AlSb and AlAs layers have an AlSb:AlAs thickness ratio of from about 10:1 to about 12:1.

63. The interband cascade laser of claim 60, wherein the AlSb and AlAs layers have an AlSb:AlAs thickness ratio of from about 4:1 to about 6:1.

64. The interband cascade laser of claim 60, wherein each AlSb layer has an average thickness of from about 5 to about 100 Å, and each AlAs layer has an average thickness of from about 1 to about 10 Å.

65. The interband cascade laser of claim 64, wherein each AlSb layer has an average thickness of from about 10 to about 50 Å, and each AlAs layer has an average thickness of from about 2 to about 5 Å.

66. The interband cascade laser of claim 49, wherein the at least one of the first and second cladding layers comprises a quaternary alloy of Al, Ga, As and Sb.

67. The interband cascade laser of claim 66, wherein the quaternary alloy is of the formula Al₁₋ₓGaₓAs_{y}Sb_{1-y}, where x is from about 0.01 to about 0.5, and y is from about 0.01 to about 0.2.

68. The interband cascade laser of claim 67, wherein x is from about 0.05 to about 0.2, and y is from about 0.05 to about 0.10.

69. The interband cascade laser of claim 67, wherein x is from about 0.05 to about 0.2, and y is from about 0.13 to about 0.19.

70. The interband cascade laser of claim 49, wherein the at least one of the first and second cladding layers comprises a ternary alloy of Al, As and Sb.

71. The interband cascade laser of claim 70, wherein the ternary alloy is of the formula AlAsₓSb₁₋ₓ, where x is from about 0.01 to about 0.2.

72. The interband cascade laser of claim 71, wherein x is from about 0.05 to about 0.15.

73. The interband cascade laser of claim 71, wherein x is from about 0.07 to about 0.10.

74. The interband cascade laser of claim 71, wherein x is from about 0.13 to about 0.19.

75. A method of making a semiconductor laser superlattice cladding layer, the method comprising depositing layers of at least three different binary materials on a substrate.

76. The method of claim 75, wherein the at least three different binary materials comprise AlSb, GaSb and AlAs.

77. The method of claim 76, wherein the AlSb layer is deposited on the AlAs layer, the GaSb layer is deposited on the AlSb layer and the AlAs layer is deposited on the GaSb layer.

78. The method of claim 76, wherein the AlSb layer is deposited on the GaSb layer, the AlAs layer is deposited on the AlSb layer and the GaSb layer is deposited on the AlAs layer.

79. The method of claim 76, wherein the GaSb layer is deposited between each of the AlAs and AlSb layers.

80. The method of claim 76, wherein the AlAs layers are deposited between each of the GaSb and AlSb layers.

81. The method of claim 76, wherein the AlSb layers are deposited between each of the GaSb and AlAs layers.

82. The method of claim 76, wherein the AlSb and AlAs layers have an AlSb:AlAs thickness ratio of from about 3:1 to about 13:1.

83. The method of claim 76, wherein the superlattice has a total thickness of from about 0.5 to about 10 microns.

84. The method of claim 76, wherein each of the AlSb layers has an average thickness of from about 5 to about 100 Å, each of the GaSb layers has an average thickness of from about 1 to about 100 Å, and each of the AlAs layers has an average thickness of from about 1 to about 10 Å.

85. The method of claim 75, wherein the superlattice has an in-plane lattice constant which substantially matches an in-plane lattice constant of the substrate.

86. The method of claim 85, wherein the substrate comprises GaSb or InAs.

87. The method of claim 75, wherein the superlattice has a thermal conductivity of at least 5 W/m-K.

88. The method of claim 75, wherein the superlattice has a refractive index less than or equal to 3.30.

89. The method of claim 75, wherein the laser cladding material is provided in an interband cascade laser.

90. A method of making a semiconductor laser superlattice cladding layer, the method comprising depositing layers of at least two different ternary materials on a substrate.

91. The method of claim 90, wherein the at least two different ternary materials comprise AlGaSb and AlGaAs.

92. The method of claim 91, wherein the AlGaSb and AlGaAs layers have an AlGaSb:AlGaAs thickness ratio of from about 3:1 to about 14:1.

93. The method of claim 91, wherein the superlattice has a total thickness of from about 0.5 to about 10 microns.

94. The method of claim 91, wherein each AlGaSb layer has an average thickness of from about 5 to about 100 Å, and each AlGaAs layer has an average thickness of from about 1 to about 10 Å.

95. The method of claim 91, wherein the AlGaSb is of the formula Al₁₋ₓGaₓSb, where x is from about 0.01 to about 0.5.

96. The method of claim 91, wherein the AlGaAs is of the formula Al_{1-y}Ga_{y}As, where y is from about 0.01 to about 0.5.

97. The method of claim 91, wherein the AlGaSb is of the formula Al₁₋ₓGaₓSb, the AlGaAs is of the formula Al_{1-y}Ga_{y}As, and x and y are substantially equal.

98. The method of claim 90, wherein the superlattice has an in-plane lattice constant which substantially matches an in-plane lattice constant of the substrate.

99. The method of claim 98, wherein the substrate comprises GaSb or InAs.

100. The method of claim 90, wherein the superlattice has a thermal conductivity of at least 5 W/m-K.

101. The method of claim 90, wherein the superlattice has a refractive index less than or equal to 3.30.

102. The method of claim 90, wherein the laser cladding material is provided in an interband cascade laser.
